(19) United States
(12) Patent Application Publication
(10) Pub. No.: US 2026/0173564 A1
(43) Pub. Date: Jun. 18, 2026

(54) HYBRID CIS/EVS IMAGE SENSOR PROVIDING HIGH EVS RESOLUTION

(71) Applicant: OMNIVISION TECHNOLOGIES, INC., Santa Clara, CA (US)

(72) Inventor: Andreas Suess, San Jose, CA (US)

(21) Appl. No.: 18/982,869

(22) Filed: Dec. 16, 2024

(51) Int. Cl. H10F 39/00; H04N 25/13; H04N 25/47; H04N 25/772; H04N 25/79; H10F 39/18

(52) U.S. Cl. CPC H10F 39/809; H04N 25/134; H04N 25/47; H04N 25/772; H04N 25/79; H10F 39/182; H10F 39/8053

(57) ABSTRACT

Hybrid CIS/EVS image sensors are disclosed herein. In one embodiment, a pixel arrangement includes a plurality of pixels and a color filter array. Each of the plurality of pixels can include a photosensor, a floating diffusion, a transfer transistor, and an EVS transistor configured to selectively couple the photosensor to an event driven circuit corresponding to the pixel. The color filter array can include a plurality of color filters arranged in a mosaic pattern over photosensors of the plurality of pixels such that the photosensor of a first pixel of the plurality of pixels corresponds to a first color and the photosensor of a second pixel of the plurality of pixels corresponds to a second color different from the first color. The event driven circuits corresponding to the plurality of pixels can be (a) different from one another and (b) selectively coupled to one another via a common node.

### TECHNICAL FIELD

This disclosure relates generally to image sensors, and in particular but not exclusively, relates to hybrid image sensors. For example, several embodiments of the present technology described in detail below are directed to pixel arrangements (and associated systems, devices, and methods) that facilitate achieving equivalent CMOS image sensor (CIS) and event vision sensor (EVS) resolutions when operated in a hybrid mode in which CIS pixels are used to capture intensity information of incident light and EVS pixels are used to capture non-CIS information (e.g., contrast information, intensity changes, event data).

### BACKGROUND

Image sensors have become ubiquitous and are now widely used in digital cameras, cellular phones, security cameras, as well as in medical, automotive, and other applications. As image sensors are integrated into a broader range of electronic devices, it is desirable to enhance their functionality, performance metrics, and the like in as many ways as possible (e.g., resolution, power consumption, dynamic range) through both device architecture design as well as image acquisition processing. The technology used to manufacture image sensors has continued to advance at a great pace. For example, the demands of higher resolution and lower power consumption have encouraged the further miniaturization and integration of these devices.

A typical image sensor operates in response to image light from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is read out as analog image signals from the column bitlines and converted to digital values to produce digital images (e.g., image data) representing the external scene. The analog image signals on the bitlines are coupled to readout circuits, which include input stages having analog-to-digital conversion (ADC) circuits to convert those analog image signals from the pixel array into the digital image signals.

### BRIEF DESCRIPTION OF THE DRAWINGS

Non-limiting and non-exhaustive embodiments of the present technology are described below with reference to the following figures, in which like or similar reference numbers are used to refer to like or similar components throughout unless otherwise specified.

FIG. 1 illustrates a stacked hybrid complementary metal oxide semiconductor (CMOS) image sensor (CIS) and event vision sensor (EVS) imaging system configured in accordance with embodiments of the present technology.

FIG. 2 illustrates a pixel arrangement with a quad Bayer color arrangement configured in accordance with embodiments of the present technology.

FIG. 3 is a partially schematic circuit diagram of a hybrid CIS/EVS imaging system configured in accordance with embodiments of the present technology.

FIGS. 4A-4C illustrate a pixel arrangement operating in various modes in accordance with embodiments of the present technology.

Skilled artisans will appreciate that elements in the figures are illustrated for simplicity and clarity and are not necessarily drawn to scale. For example, the dimensions of some of the elements in the figures may be exaggerated relative to other elements to aid in understanding of various aspects of the present technology. In addition, common but well-understood elements or methods that are useful or necessary in a commercially feasible embodiment are often not depicted in the figures, or described in detail below, to avoid unnecessarily obscuring the description of various aspects of the present technology.

### DETAILED DESCRIPTION

The present disclosure relates to hybrid CIS/EVS imaging systems providing high EVS resolution, and to associated systems, devices, and methods. For example, several embodiments of the present technology are directed to image sensors that can be operated in a hybrid mode to provide equivalent CIS and EVS resolutions. Such image sensors can include a plurality of pixels, each pixel including an EVS transistor selectively coupling a first photosensor of the pixel to an event driven circuit corresponding to the pixel. In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

It will be understood that, although the terms first, second, third, etc., may be used in the disclosure and claims to describe various elements, these elements should not be limited by these terms and should not be used to determine the process sequence or formation order of associated elements. Unless otherwise indicated, these terms are merely used to distinguish one element from another element. Thus, a first element discussed below could be termed a second element without departing from the teachings of the disclosed embodiments.

It is appreciated that the term “photosensor” or “photodiode” may correspond to a doped region disposed within the semiconductor material configured to photogenerate image charge(s) (e.g., one or more electrons or holes) in response to incident light. For example, photodiode may correspond to an n-doped region disposed within a p-type semiconductor material or an n-doped region surrounded by a p-type well disposed within the semiconductor material or a p-doped region disposed within an n-type semiconductor.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### A. Overview

Hybrid CIS/EVS imaging systems providing high EVS resolution (and associated systems, devices, and methods) are disclosed. For example, several embodiments of the present technology are directed to various imaging systems with event driven circuits dedicated to individual pixels that can be operated in a hybrid mode to simultaneously provide CIS information and EVS information at a same resolution as the CIS information. Although normal image sensors offer great image capturing and event detection capabilities, one of the limitations with normal image sensors is that normal image sensors do not provide sufficiently high EVS resolution or scalability. Attempts to provide typical image sensors with such EVS resolution and scalability have resulted in compromised solutions that have higher latency compared to their normal image sensor counterparts.

It is appreciated that circuit designs configured in accordance with various embodiments of the present technology address at least some of the issues discussed above. For example, a pixel arrangement disclosed herein can include a plurality of pixels, each pixel selectively coupled to an event driven circuit dedicated to that particular pixel. More specifically, each pixel can include a plurality of photosensors and an EVS transistor that selectively couples one or more of the photosensors to the dedicated event driven circuit. Because the dedicated event driven circuit is coupled to one or more photosensors of a single pixel, each pixel can provide its own CIS and EVS information. Therefore, the EVS information can be collected on a per-pixel basis, enabling provision of EVS information at a same resolution as CIS information.

Thus, as will be shown and described in the various examples below, a pixel arrangement configured in accordance with some embodiments of the present technology can include a plurality of pixels (e.g., four pixels) and a color filter array. Each of the plurality of pixels can include a photosensor configured to photogenerate image charge in response to incident light, a floating diffusion configured to receive the image charge from the photosensor, a transfer transistor configured to selectively couple the photosensor to the floating diffusion, and an EVS transistor configured to selectively couple the photosensor to an event driven circuit corresponding to the pixel. The color filter array can include a plurality of color filters arranged in a mosaic pattern over photosensors of the plurality of pixels such that the photosensor of a first pixel of the plurality of pixels corresponds to a first color and the photosensor of a second pixel of the plurality of pixels corresponds to a second color different from the first color. The event driven circuits corresponding to the plurality of pixels can be (a) different from one another and (b) selectively coupled to one another via a common node.

An imaging system configured in accordance with some embodiments of the present technology can include a plurality of pixels, a color filter array, a plurality of event driven circuits, and a threshold comparison stage. Each of the plurality of pixels can include a plurality of photosensors, each configured to photogenerate image charge in response to incident light, a floating diffusion configured to receive the image charge from the plurality of photosensors, a plurality of transfer transistors, each configured to selectively couple a corresponding one of the plurality of photosensors to the floating diffusion, and an EVS transistor. The color filter array can include a plurality of color filters arranged in a mosaic pattern over corresponding ones of the plurality of photosensors such that (a) the plurality of photosensors of a first pixel of the plurality of pixels corresponds to a first color and (b) the plurality of photosensors of a second pixel of the plurality of pixels corresponds to a second color different from the first color. Each of the plurality of event driven circuits can be coupled to a corresponding one of the plurality of pixels. The EVS transistor of each of the plurality of pixels can be configured to selectively couple a first photosensor of the plurality of photosensors of that pixel to a corresponding one of the plurality of event driven circuits. The threshold comparison stage can be coupled to each of the plurality of event driven circuits.

The present technology is expected to offer several advantages. For example, the present technology is expected to, when operating in a hybrid CIS/EVS mode, provide higher EVS resolution (e.g., equivalent to the CIS resolution provided). Also, each pixel can be operable to provide its own EVS information independently of other pixels, so EVS information can be paired with CIS information on a per-pixel basis. This can enable matching of color channels between EVS information and CIS information. In addition to providing higher image quality, the present technology is expected to improve scalability by, for example, sharing a threshold comparison stage amongst multiple event driven circuits that are each dedicated to individual pixels.

### B. Selected Embodiments of Hybrid CIS/EVS Image Sensors, and Associated Systems, Devices, and Methods

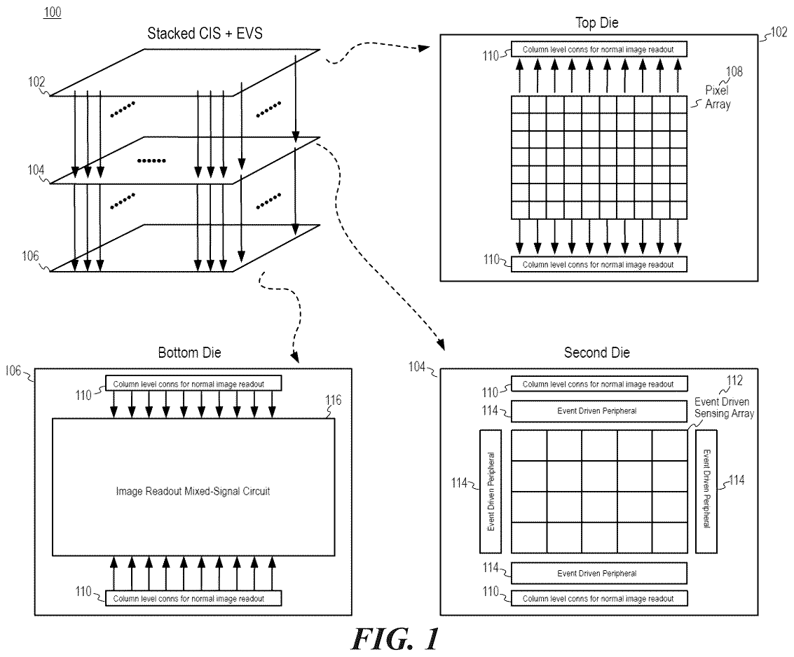

FIG. 1 illustrates a stacked hybrid complementary metal oxide semiconductor (CMOS) image sensor (CIS) and event vision sensor (EVS) imaging system 100 (“the system 100”) configured in accordance with embodiments of the present technology. As shown in the depicted example, the system 100 includes a first die 102, a second die 104, and a third die 106 that are stacked and coupled together in a stacked chip scheme. In various examples, the first die 102, the second die 104, and the third die 106 are semiconductor dies that include a suitable semiconductor material such as silicon. In the example, the first die 102, which may also be referred to as the top die 102 of the system 100, includes a pixel array 108. The third die 106, which may also be referred to as the bottom die 106 of the system 100, includes an image readout circuit 116 (also referred to herein as image readout mixed-signal circuitry). The image readout circuit 116 can be coupled to the pixel array 108 of the top die 102 through column level connections for normal image readout 110. In various examples, the column level connections for normal image readout 110 are implemented from column bitlines of the pixel array 108 with through silicon vias (TSVs) that extend between the top die 102 and the bottom die 106, and are routed through the second die 104.

In various examples, the pixel array 108 is a two-dimensional (2D) array including a plurality of pixels (also referred to as “pixels cells”) that each includes at least one photosensor exposed to incident light. As illustrated in the depicted example, the pixels are arranged into rows and columns to acquire image data of a person, place, object, etc., which can then be used to render images and/or video of a person, place, object, etc. As discussed further herein, each of the pixels can be a hybrid CIS/EVS pixel including a plurality of photosensors (e.g., photodiodes) configured to photogenerate image charge in response to the incident light. The pixel array 108 can be operated in a CIS-only mode, a hybrid CIS/EVS mode, and/or an EVS-only mode. When operating in the CIS-only or hybrid CIS/EVS mode, the appropriate fraction of the analog image charge data acquired can be read out by the image readout circuit 116 in the bottom die 106 through the column bitlines. In various examples, the image charge from each row of the pixel array 108 can be read out in parallel through column bitlines by the image readout circuit 116.

In various examples, the image readout circuit 116 in the bottom die 106 includes amplifiers, analog to digital converter (ADC) circuitry, associated analog support circuitry, associated digital support circuitry, etc., for normal image readout and processing. In some examples, image readout circuit 116 may also include event driven readout circuitry, which will be described in greater detail below. In operation, the photogenerated analog image charge signals are read out from the pixels of the pixel array 108, amplified, and converted to digital values in the image readout circuit 116. In some examples, the image readout circuit 116 can read out a row of image data at a time. In other examples, the image readout circuit 116 can read out the image data using a variety of other techniques (not illustrated), such as a serial readout or a full parallel readout of all pixels simultaneously. The image data may be stored or even manipulated by applying post image effects (e.g., crop, rotate, remove red eye, adjust brightness, adjust contrast, and the like).

In the depicted example, the second die 104, which may also be referred to as the middle die 104 of the system 100, includes an event driven sensing array 112 that is coupled to the pixel array 108 in the top die 102. In various examples, the event driven sensing array 112 is coupled to the pixels of the pixel array 108 through one or more stacked pixel level connections (SPLC) (e.g., hybrid bonds) disposed between the top die 102 and the middle die 104. In one example, the event driven sensing array 112 includes an array of event driven circuits. As will be discussed, in one example, each of the event driven circuits in the event driven sensing array 112 is coupled to a corresponding one of the plurality of pixels of the pixel array 108 (e.g., through at least one hybrid bond between the top die 102 and the middle die 104) to asynchronously detect events that occur in the light that is incident upon the pixel array 108 in accordance with embodiments of the present technology.

When operating in the hybrid CIS/EVS or EVS-only mode, the appropriate fraction of the photosensors of each of the pixels of the pixel array 108 can be used to track changes in the intensity of light incident on the photosensors from an external scene. In particular, the photosensors can photogenerate image charge (electrons or holes) or photocurrent in response to the incident light from the external scene. The photogenerated image can then be provided, via an EVS connection such as a hybrid bond, to a coupled event driven circuit of the event driven sensing array 112. In some embodiments, each event driven circuit includes (i) a photocurrent-to-voltage converter coupled to one or more photosensors of the corresponding pixel to convert photocurrent generated by the one or more photosensors to a voltage, and (ii) a difference circuit coupled to the photocurrent-to-voltage converter and configured to generate a difference signal or analog signal level (e.g., a logarithmic difference voltage relative to a reset time) based at least in part on the voltage. The event driven sensing array 112 and/or event driven peripheral circuitry 114 on the middle die 104 can further include a threshold comparison stage to determine and generate event detection signals in response to events asynchronously detected in incident light received from the external scene. For example, the threshold comparison stage may generate an event detection signal when a detected change in the pixel signal at the output of the difference circuit relative to a reference pixel signal is greater than a predetermined voltage threshold value. It is appreciated that the described event driven readout circuit is one example implementation to read out event signals. Various implementations for readout circuitry and readout schemes for event vision sensor pixels are well known. Thus, details on circuitry and readout techniques for event driven circuits are largely omitted here for the sake of brevity and to avoid obscuring aspects of the present technology.

As shown, the event driven peripheral circuitry 114 can be arranged around the periphery of the event driven sensing array 112 in the middle die 104. In various examples, the event driven peripheral circuitry 114 can receive and process corresponding event detection signals. The depicted example also illustrates the column level connections for normal image readout 110 that are routed through the middle die 104 between the top die 102 and the bottom die 106.

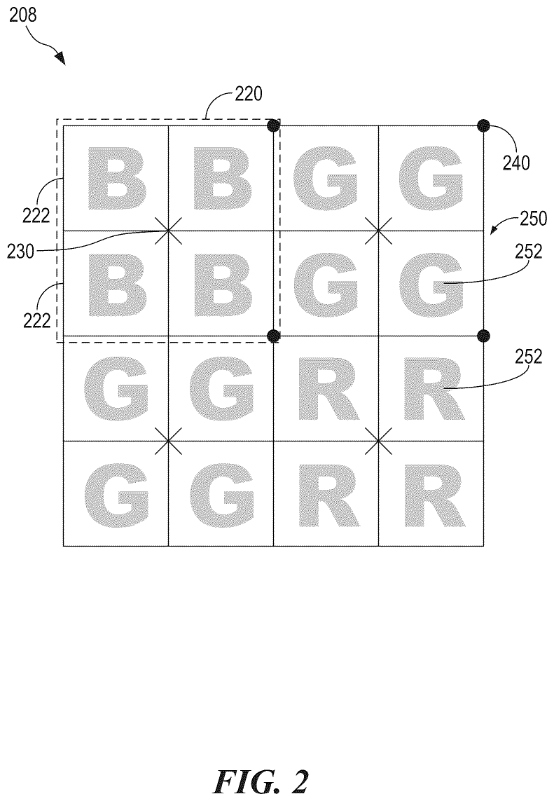

FIG. 2 illustrates a pixel arrangement 208 and an associated quad Bayer color filter array 250, each configured in accordance with various embodiments of the present technology. It is appreciated that the pixel arrangement 208 of FIG. 2 may be an example of the pixel array 108 (or a portion thereof) included in the system 100 of FIG. 1 and/or of other pixel arrays configured in accordance with various embodiments of the present technology, and that similarly named and numbered elements described above are coupled and function similarly below.

The pixel arrangement 208 can include a plurality of pixels 220 arranged in rows and columns, and each of the plurality of pixels 220 can include a plurality of sub-pixels 222 and a floating diffusion 230 (shown as an “X”). In the illustrated embodiment, four pixels 220 are arranged in a 2×2 pattern, each pixel 220 includes four sub-pixels 222 arranged in a 2×2 pattern, and each floating diffusion 230 is coupled to each of the four sub-pixels 222 of the corresponding pixel 220. As described in further detail herein, each sub-pixel 222 can include a photosensor and a transfer transistor selectively coupling the photosensor to its respective floating diffusion. It is appreciated that the pixel arrangement 208 can include a different number of pixels 220 and/or each pixel 220 can include a different number of sub-pixels 222. For example, the four pixels 220 arranged in the illustrated 2×2 pattern can be repeated any number of times to form a larger pixel array (e.g., a 50 MP array).

The quad Bayer color filter array 250 can include a plurality of color filters 252 arranged in a mosaic pattern over corresponding ones of the sub-pixels 222 (e.g., over corresponding ones of the plurality of photosensors thereof). In the illustrated embodiment, the quad Bayer color filter array 250 includes (i) blue (B) color filters 252 disposed over the sub-pixels 222 of the top-left pixel 220, (ii) green (G) color filters 252 disposed over the sub-pixels 222 of the top-right pixel 220 and the bottom-left pixel 220, and (iii) red (R) color filters 252 disposed over the sub-pixels 222 of the bottom-right pixel 220. Therefore, the sub-pixels 222 of any given pixel 220 can be disposed under color filters 252 of the same color. It is appreciated that the quad Bayer color filter array 250 can be substituted with a different color filter array, such as a Bayer color filter array in which a single color filter 252 is placed over all four sub-pixels 222 of a same pixel 220.

The pixel arrangement 208 can further include a plurality of EVS connection nodes 240. More specifically, in the illustrated embodiment, each pixel 220 of the pixel arrangement 208 includes an EVS connection node 240 positioned at its top-right corner. Therefore, assuming that the pixel arrangement 208 includes a repeating pattern of the illustrated four pixels 220, the number of EVS connection nodes 240 can be equal to the number of pixels 220. In other embodiments of the present technology, the EVS connection node 240 for a given pixel 220 of the arrangement 208 can be positioned at another location about and/or within the pixel 220, such as at another one of the corners besides the top-right corner. As discussed in further detail below, in some embodiments, each EVS connection node 240 can be dedicated to one (e.g., only one) of the pixels 220, and can receive photocurrent therefrom for subsequent event detection processing. Accordingly, in some embodiments, each pixel 220 is associated with one floating diffusion 230 and one EVS connection node 240.

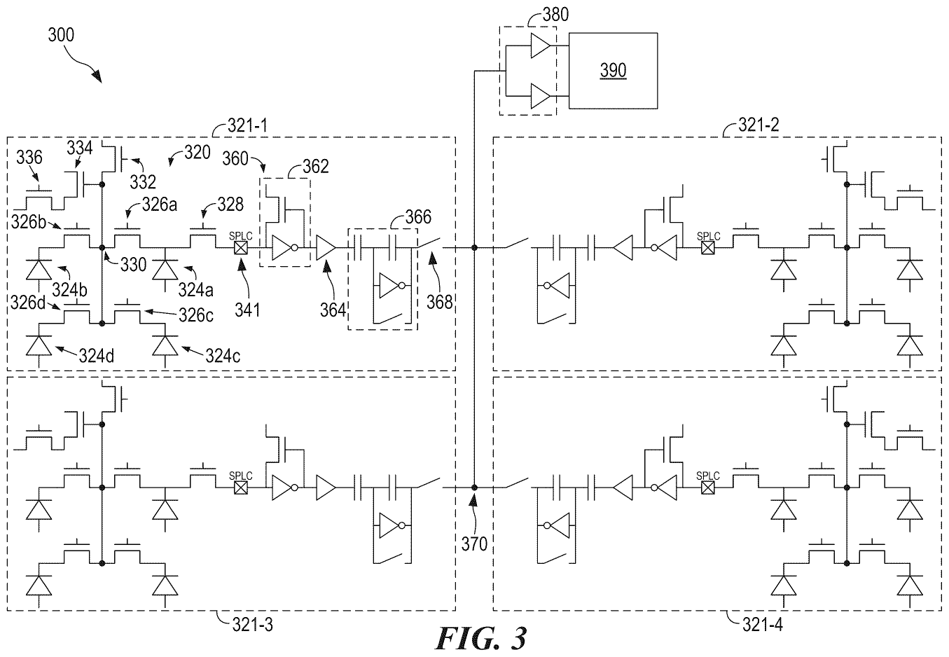

FIG. 3 illustrates a hybrid CIS/EVS imaging system 300 (“the system 300”) configured in accordance with various embodiments of the present technology. The system 300 is also referred to herein as a hybrid image sensor. It is appreciated that the system 300 of FIG. 3 may be an example of the system 100 of FIG. 1 and/or of other systems configured in accordance with various embodiments of the present technology, and that similarly named and numbered elements described above are coupled and function similarly below.

The system 300 can include a plurality of hybrid units (four shown in FIG. 3, individually labeled 321-1, 321-2, 321-3, 321-4, and collectively referred to as “the hybrid units 321”). Referring to the hybrid unit 321-1 as a representative example of each of the hybrid units 321, each of the hybrid units 321 can include a pixel 320 and an event driven circuit 360 coupled to the pixel 320. In some embodiments, the pixel 320 is included on a first die (e.g., the top die 102 of FIG. 1), and the event driven circuit 360 is included on a second die (e.g., the middle die 104). The event driven circuit 360 can be coupled to its corresponding pixel 320 via a stacked pixel level connection (SPLC) 341 (e.g., a hybrid bond). The SPLC 341 can correspond to the EVS connection node 240 of FIG. 2.

The pixel 320 can include a plurality of photosensors (four shown in FIG. 3, individually labeled 324a, 324b, 324c, 324d, in the top-left pixel 320; and collectively referred to as “the photosensors 324”), a plurality of transfer transistors (e.g., four shown in FIG. 3, individually labeled 326a, 326b, 326c, 326d in the top-left pixel 320; collectively referred to as “the transfer transistors 326”; and each corresponding to a unique one of the photosensors 324 of the pixel 320), and a floating diffusion 330. The plurality of photosensors 324 can be configured to photogenerate image charge in response to incident light. Each transfer transistor 326 is configured to selectively couple a corresponding one of the plurality of photosensors 324 to the floating diffusion 330 based at least in part on a control signal applied to its gate. The floating diffusion 330 can be configured to receive image charge from the plurality of photosensors 324. In some embodiments, the pixel 320 includes four sub-pixels (e.g., similar to the sub-pixels 222 of FIG. 2), with each sub-pixel including (or formed by) a unique pair of one of the photosensors 324 and one of the transfer transistors 326. Moreover, each photosensor 324 can be disposed under a color filter (e.g., similar to one of the color filters 252 of FIG. 2), and photosensors 324 included in the same pixel 320 can be disposed under color filters of the same color. For example, correlating FIG. 3 to FIG. 2, (i) the photosensors 324 of the pixel 320 in the first hybrid unit 321-1 can be disposed under blue color filters, (ii) the photosensors of the pixel in the second hybrid unit 321-2 and of the pixel in the third hybrid unit 321-3 can be disposed under green color filters, and (iii) the photosensors of the pixel in the fourth hybrid unit 321-4 can be disposed under red color filters.

Referring again to the hybrid unit 321-1 as a representative example of each of the hybrid units 321-1, 321-2, 321-3, and 321-4, the pixel 320 can further include a reset transistor 332, a source follower transistor 334, a row select transistor 336, and an EVS transistor 328. The reset transistor 332 can selectively couple the floating diffusion 330 to a supply voltage (not shown). A gate of the source follower transistor 334 can be coupled to the floating diffusion 330 (e.g., coupled to a node between the floating diffusion 330 and the reset transistor 332). The row select transistor 336 can selectively couple the source follower transistor 334 to a bitline (not shown). The EVS transistor 328 can be configured to selectively couple the first photosensor 324a of the plurality of photosensors 324 to the event driven circuit 360 included in the same hybrid unit 321 (e.g., via the SPLC 341) based at least in part on a corresponding control signal applied to the gate of the EVS transistor 328.

The event driven circuit 360 can include a photocurrent-to-voltage converter 362 and a difference circuit 366. The photocurrent-to-voltage converter 362 can be coupled to the EVS transistor 328 (e.g., via the SPLC 341) and can be configured to convert photocurrent generated by one or more of the photosensors 324 to a voltage. In some embodiments, the photocurrent-to-voltage converter 362 can be a logarithmic amplifier.

The difference circuit 366 can be coupled to the photocurrent-to-voltage converter 362 and can be configured to (a) store a reference voltage at a reset time and (b) thereafter generate a difference signal or analog signal level (e.g., a logarithmic difference voltage relative to the reset time) based at least in part on the voltage from the photocurrent-to-voltage converter 362. The difference circuit 366 can therefore include memory elements (e.g., one or more capacitors) to store the reference voltage and/or the difference signal. Because the reference voltage and the difference signal correspond to image charge photogenerated by a photosensor corresponding to a single color/color channel (as discussed above), the memory elements of the difference circuit can also be referred to herein as “color-specific memory elements.” In some embodiments, the event driven circuit 360 additionally includes a buffer 364 coupled between the photocurrent-to-voltage converter 362 and the difference circuit 366 (e.g., to mitigate kickback from the difference circuit 366 to the photocurrent-to-voltage converter 362).

The system 300 can further include a threshold comparison stage 380 and a logic and handshake circuit 390. In some embodiments, the threshold comparison stage 380 includes an up event comparator and a down event comparator coupled in parallel between (i) the plurality of event driven circuits 360 of the hybrid units 321-1, 321-2, 321-3, 321-4 and (ii) the logic and handshake circuit 390. In particular, the threshold comparison stage 380 can be coupled to a shared node 370 that is coupled to each of the plurality of event driven circuits 360 included in the hybrid units 321. In some embodiments, each hybrid unit 321 further includes a switch 368 selectively coupling the corresponding event driven circuit 360 to the shared node 370, and thus to the threshold comparison stage 380. The switches 368 can be controlled independently and/or in groups to facilitate coupling the event drive circuits 360 to the shared node 370 independently and/or in groups. The threshold comparison stage 380 can be configured to determine and generate event detection signals in response to events asynchronously detected in incident light received from the external scene. For example, the threshold comparison stage 380 can assert an event detection signal when the output signal of the difference circuit 366 of a coupled event driven circuit 360 is greater than a predetermined voltage threshold value, indicating that the corresponding pixel 320 has detected an event in the external scene. Event detection signals generated by the threshold comparison stage 380 are output to the logic and handshake circuit 390. In turn, the logic and handshake circuit 390 can be configured to process the event detection signals. Additional details regarding photocurrent-to-voltage converters, difference circuits, threshold comparison stages, and logic and handshake circuits are provided in U.S. patent application Ser. No. 17/875,244, titled “LOW POWER EVENT DRIVEN PIXELS WITH ACTIVE DIFFERENCE DETECTION CIRCUITRY, AND RESET CONTROL CIRCUITS FOR THE SAME,” and filed on Jul. 27, 2022, the disclosure of which is incorporated by reference herein in its entirety.

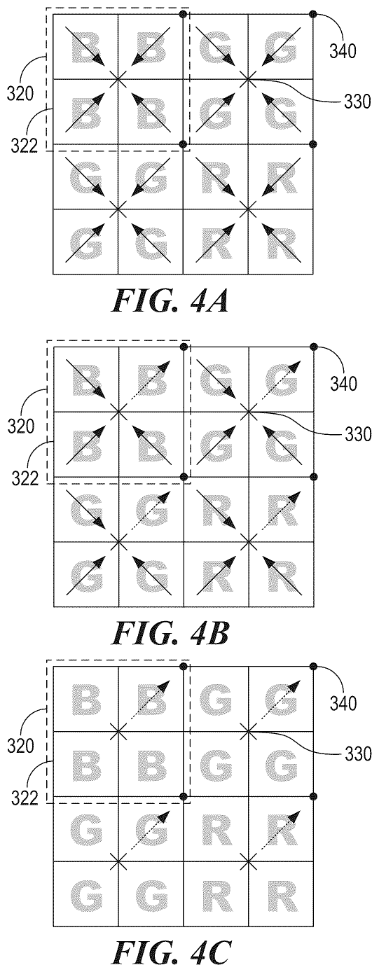

In operation, the system 300 can be operated in a CIS-only mode, a hybrid CIS/EVS mode, and/or an EVS-only mode. When operating in the CIS-only mode, during an exposure or integration period, each of the EVS transistors 328 can be deactivated. Then, during a readout period following the exposure period, each of the transfer transistors 326 can be activated while each of the EVS transistors 328 remain deactivated. Referring momentarily to FIG. 4A, the figure illustrates solid arrows, each representing image charges photogenerated by the photosensor 324 in a respective sub-pixel 322, pointing towards the floating diffusion 330 of the corresponding pixel 320. Therefore, the image charges photogenerated by the photosensors 324 of each pixel 320 can be transferred to the floating diffusion 330 of the pixel 320 (independently or simultaneously) via corresponding transfer transistors 326, and one or more corresponding signals can be read out via the corresponding source follower transistor 334 and the corresponding row select transistor 336. Accordingly, when operating in the CIS-only mode, all or a subset of the photosensors 324 of a pixel 320 can be utilized for generating CIS information while none of the photosensors 324 of the pixel 320 are used for generating EVS (non-CIS) information.

Referring back to FIG. 3, when operating the system 300 in the hybrid CIS/EVS mode, during an exposure or integration period, the EVS transistor 328 of each hybrid unit 321 can be activated while the transfer transistor 326a of each hybrid unit 321 that selectively couples the first photosensor 324a of the hybrid unit 321 to the floating diffusion 330 of the corresponding pixel 320 is deactivated. Then, during a readout period, the EVS transistor 328 can be deactivated and/or the transfer transistors 326b-326d of the hybrid unit 321 can be activated. The transfer transistor 326a remains deactivated for the duration of the readout period. Referring momentarily to FIG. 4B, the figure illustrates (i) solid arrows, each representing image charges photogenerated by one of the photosensor 324b-324d in one of three sub-pixels 322, pointing towards the floating diffusion 330 of the corresponding pixel 320, and (ii) dotted arrows, each representing photocurrent generated by the photosensor 324a in the remaining one of the sub-pixels 322 of the corresponding pixel 320, pointing towards the EVS connection node 340 associated with the corresponding pixel 320. Therefore, the image charges photogenerated by the second, third, and fourth photosensors 324b, 324c, 324d of a pixel 320 can be transferred to the floating diffusion 330 of the pixel 320 (independently from one another or simultaneously), and one or more corresponding signals can be read out of the pixel 320 via the corresponding source follower transistor 334 and the corresponding row select transistor 336. The photocurrent generated by the first photosensor 324a of the pixel 320 can be transferred (during and/or after the exposure period) to the corresponding event driven circuit 360, as opposed to the floating diffusion 330 of the pixel 320. Accordingly, when operating in the hybrid CIS/EVS mode, a fraction (e.g., 25%) of the photosensors 324 of each pixel 320 can be utilized for generating EVS information, and the remaining fraction (e.g., 75%) of the photosensors 324 can be utilized for generating CIS information. Thus, in embodiments in which the image charges photogenerated by the photosensors 324b-324d are transferred to the floating diffusion 330 of the corresponding pixel 320 such that they are binned and read out of the pixel 320 together, the system 300 facilitates obtaining one CIS signal (corresponding to image charge photogenerated by the photosensors 324b-324d of the pixel 320) and one EVS signal (corresponding to image charge photogenerated by the photosensor 324a of the pixel 320) per pixel 320/hybrid unit 321. In other words, when operated in the hybrid CIS/EVS mode, the system 300 can provide a same CIS resolution and EVS resolution.

Notably, when operating in the hybrid CIS/EVS mode, each individual pixel 320 can simultaneously provide both CIS information and EVS information independently of other pixels 320. In particular, because each event driven circuit 360 is dedicated to a single pixel 320, the EVS information can be provided on a per-pixel basis, for example, without necessarily mixing with EVS information provided by other pixels 320. In some embodiments, the system 300 is operable in a monochrome CIS/EVS hybrid mode in which the EVS information from different pixels 320 disposed under different colored ones of the color filters are mixed prior to reaching the threshold comparison stage 380. For example, each of the switches 368 can be activated such that EVS information from the plurality of pixels 320 is mixed (or combined) at the shared node 370. In embodiments in which the four illustrated pixels 320 are disposed under the quad Bayer color filter array 250 of FIG. 2, the combined EVS information can be B+2G+R, which can effectively be monochrome.

In some embodiments, the system 300 is operable in a color CIS/EVS hybrid mode in which the EVS information from different pixels 320 disposed under different colored ones of the color filters reach the threshold comparison stage at different times without mixing (or combining). For example, the switches 368 can be activated in a staggered manner such that the EVS information from each pixel 320 is transmitted to the threshold comparison stage 380 one at a time. Alternatively, the switches 368 can be activated in a staggered manner such that EVS information from each pixel 320 of a same color is transmitted to the threshold comparison stage 380 at a same time. For example, assuming that the pixels in the bottom left and the top right of the system 300 of FIG. 3 both correspond to a same color while the pixels in the top left and bottom right of the system 300 correspond to one or more different colors, the switches 368 corresponding to the bottom left and top right pixels can be activated together while the switches 368 corresponding to the top left and bottom right pixels are not activated such that EVS information from the top right and bottom left pixels are transmitted to the threshold comparison stage 380 together and independently from EVS information corresponding to the top left and bottom right pixels. Therefore, when operated in the color CIS/EVS hybrid mode, the different EVS information can be associated with a single pixel 320 or a single color. In particular, the EVS resolution can be equivalent to the CIS resolution (e.g., per pixel 320, per color channel, etc.).

Referring back to FIG. 3, when operating the system 300 in the EVS-only mode, the EVS transistor 328 of each hybrid unit 321 can be activated while the transfer transistor 326a of each hybrid unit 321 that selectively couples the first photosensor 324a of the hybrid unit 321 to the floating diffusion 330 of the corresponding pixel 320 is deactivated. As a result, image charge photogenerated by the photosensor 324a of each pixel 320 can be transferred to the corresponding event driven circuit 360 and then to threshold comparison stage 380 according to a timing when the corresponding switch 368 is activated. Image charge photogenerated by the photosensors 324b-324d of each pixel 320 can be discarded, such as via the transfer transistors 326b-326d and the reset transistor 332 of the corresponding pixel 320. Alternatively, the image charges photogenerated by the photosensors 324b-324d of each pixel can be transferred via a corresponding one of the transfer transistors 326b-326d, the transfer transistor 326a, and the EVS transistor 328 to the event drive circuit 360 of the corresponding pixel 320. Referring momentarily to FIG. 4C, the figure illustrates dashed arrows, each representing image charges photogenerated by the photosensors 324 in a respective sub-pixel 322 of a corresponding pixel 320, pointing towards the corresponding EVS connection node 340. Accordingly, when operating in the EVS-only mode, all or a subset of the photosensors 324 of a pixel 320 can be utilized for generating EVS information while none of the photosensors 324 of the pixel 320 are used for generating CIS information.

In the illustrated embodiment of FIG. 3, each pixel 320 includes a single EVS transistor 328. Therefore, when operating in the hybrid CIS/EVS mode, each pixel 320 sacrifices 25% of its photosensors 324 for providing EVS information, and uses the remaining 75% of the photosensors 324 for providing CIS information. In other embodiments, each pixel 320 can include one or more additional EVS transistors 328. For example, in each pixel 320, (i) a second EVS transistor (not shown) can selectively couple the second photosensor 324b to the event driven circuit 360, (ii) a third EVS transistor (not shown) can selectively couple the third photosensor 324c to the event driven circuit 360, and/or (iii) a fourth EVS transistor (not shown) can selectively couple the fourth photosensor 324d to the event driven circuit 360. In some embodiments, the additional EVS transistors 328 selectively couple the corresponding photosensors 324 to event driven circuits 360 in other hybrid units 321. Accordingly, based on the number of additional EVS transistors, when operating in the hybrid CIS/EVS mode, each pixel 320 can sacrifice a different fraction of the photosensors 324 (e.g., 50%, 75%) for providing EVS information, and use the remaining photosensors 324 (e.g., 50%, 25%) for providing CIS information. In some embodiments, each pixel 320 includes the same number of EVS transistors 328 as photosensors 324, and each photosensor 324 can be selectively coupled to the event driven circuit 360 via the corresponding EVS transistor 328. Therefore, in such embodiments, the system 300 can be operated in an EVS-only mode in which all of the photosensors 324 of a pixel 320 are used to obtain respective EVS information via a different event driven circuit 360, as described in further detail below. when operating in the EVS-only mode, the EVS transistors 328 can be activated, and the transfer transistors 326 can be deactivated. More specifically, photocurrent generated by each of the photosensors 324 of a pixel 320 can be read out to a respective (e.g., unique) event driven circuit 360 via a respective (e.g., unique) EVS transistor 228 and a respective (e.g., unique) EVS connection node 340 (e.g., placed at one of the corners of the pixel 320). Accordingly, when operating in the EVS-only mode, all of the photosensors 324 (e.g., 100%) of a pixel 320 are utilized for generating EVS information, and none of the photosensors 324 are utilized for generating CIS information. In embodiments in which adjacent pixels 320 correspond to the different colors yet share an EVS connection node 340, the shared EVS connection node 340 can receive photocurrents associated with multiple different colors.

Referring to FIGS. 1-4 together, embodiments of the present technology, when operating in the hybrid CIS/EVS mode, can provide EVS information at a per-pixel and/or per-color-channel basis. Thus, the EVS resolution, which can be equivalent to the CIS resolution provided, can be higher than that of other imaging systems. Also, because each pixel can be operable to provide its own EVS information independently of other pixels, any specific color associated with the EVS information from a single pixel can be preserved (e.g., stored separately) during readout. In addition to providing higher image quality, embodiments of the present technology are expected to be scalable. For example, as shown in FIG. 3, the threshold comparison stage 380 can be operably coupled to multiple event driven circuits 360, each dedicated to individual ones of the pixels 320. As a result, few threshold comparison stages 380 can be used, enabling improved scalability.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A pixel arrangement, comprising:
a plurality of pixels, each of the plurality of pixels including:
a photosensor configured to photogenerate image charge in response to incident light,
a floating diffusion configured to receive the image charge from the photosensor,
a transfer transistor configured to selectively couple the photosensor to the floating diffusion, and
an event vision sensor (EVS) transistor configured to selectively couple the photosensor to an event driven circuit corresponding to the pixel; and
a color filter array including a plurality of color filters arranged in a mosaic pattern over photosensors of the plurality of pixels such that the photosensor of a first pixel of the plurality of pixels corresponds to a first color and the photosensor of a second pixel of the plurality of pixels corresponds to a second color different from the first color,
wherein the event driven circuits corresponding to the plurality of pixels (a) are different from one another and (b) are selectively coupled to one another via a common node.

2. The pixel arrangement of claim 1, wherein:
the event driven circuit corresponding to the first pixel is dedicated to the first pixel; and
the event driven circuit corresponding to the second pixel is dedicated to the second pixel.

3. The pixel arrangement of claim 1, wherein:
the event driven circuit corresponding to the first pixel includes memory elements corresponding to only the first color; and
the event driven circuit corresponding to the second pixel includes memory elements corresponding to only the second color.

4. The pixel arrangement of claim 1, wherein each of the plurality of pixels further comprises a plurality of photosensors including the photosensor, and wherein each photosensor of the plurality of photosensors is configured to generate corresponding image charge in response to corresponding incident light.

5. The pixel arrangement of claim 4, wherein the first pixel or the second pixel includes only one photosensor that is configured to transfer the corresponding image charge to a corresponding event driven circuit.

6. The pixel arrangement of claim 4, wherein the first pixel or the second pixel further includes a second EVS transistor that is configured to selectively couple a second one of the plurality of photosensors of that pixel to a corresponding event driven circuit.

7. The pixel arrangement of claim 4, wherein:
the plurality of photosensors of each pixel of the plurality of pixels includes four photosensors positioned in a 2×2 arrangement such that floating diffusion of that pixel is configured to receive the corresponding image charge from each of the four photosensors; and
the pixel arrangement is operable in a CMOS image sensor (CIS)/EVS hybrid mode in which (i) 25%, 50%, or 75% of the four photosensors of each of the plurality of pixels is/are configured to provide EVS information and (ii) remaining ones of the four photosensors of each of the plurality of pixels is/are configured to provide CIS information.

8. The pixel arrangement of claim 4, wherein each of the plurality of pixels includes a plurality of transfer transistors including the transfer transistor, and wherein each transfer transistor of the plurality of transfer transistors is configured to selectively couple a corresponding one of the plurality of photosensors to the floating diffusion.

9. The pixel arrangement of claim 8, wherein each of the plurality of pixels is operable in a CMOS image sensor (CIS)-only mode by activating each of the plurality of transfer transistors and deactivating the EVS transistor.

10. The pixel arrangement of claim 8, wherein each of the plurality of pixels is operable in a CMOS image sensor (CIS)/EVS hybrid mode by activating the EVS transistor, deactivating the transfer transistor configured to selectively couple the photosensor to the floating diffusion, and activating remaining ones of the plurality of transfer transistors.

11. The pixel arrangement of claim 10, wherein:
when operating in the CIS/EVS hybrid mode, each of the plurality of pixels is configured to simultaneously provide EVS information and CIS information and independently of other ones of the plurality of pixels; and
the EVS information and CIS information provided by any given one of the plurality of pixels each correspond to a same color associated within one of the plurality of color filters.

12. The pixel arrangement of claim 1, wherein each of the first and second pixels is operable in an EVS-only mode by activating the EVS transistor and deactivating each of the plurality of transfer transistors.

13. The pixel arrangement of claim 1, wherein the plurality of pixels includes a third pixel and a fourth pixel, and wherein the plurality of color filters are arranged in the mosaic pattern over the photosensors of the plurality of pixels such that the photosensor of the third pixel or the photosensor of the fourth pixel corresponds to a third color different from the first and second colors.

14. The pixel arrangement of claim 1, wherein the plurality of pixels includes a third pixel and a fourth pixel, and wherein the plurality of color filters are arranged in the mosaic pattern over the photosensors of the plurality of pixels such that the photosensor of the third pixel or the photosensor of the fourth pixel corresponds to the first color or the second color.

15. The pixel arrangement of claim 1, wherein the plurality of pixels includes a third pixel and a fourth pixel, and wherein the color filter array includes a quad Bayer color filter array, wherein the plurality of color filters includes:
a red color filter disposed over the photosensor of the first pixel;
a first green color filter disposed over the photosensor of the second pixel;
a second green color filter disposed over the photosensor of the third pixel; and
a blue color filter disposed over the photosensor of the fourth pixel.

16. The pixel arrangement of claim 1, wherein each of the plurality of pixels further includes a reset transistor selectively coupling the floating diffusion to a supply voltage, a source follower transistor having a gate coupled to the floating diffusion, and a row select transistor selectively coupling the source follower transistor to a bitline.

17. An imaging system, comprising:
a plurality of pixels, each of the plurality of pixels including:
a plurality of photosensors, each configured to photogenerate image charge in response to incident light,
a floating diffusion configured to receive the image charge from each of the plurality of photosensors,
a plurality of transfer transistors, each configured to selectively couple a corresponding one of the plurality of photosensors to the floating diffusion, and
an event vision sensor (EVS) transistor;
a color filter array including a plurality of color filters arranged in a mosaic pattern over corresponding ones of the plurality of photosensors such that the plurality of photosensors of a first pixel of the plurality of pixels corresponds to a first color and the plurality of photosensors of a second pixel of the plurality of pixels corresponds to a second color different from the first color;
a plurality of event driven circuits, each of the plurality of event driven circuits coupled to a corresponding one of the plurality of pixels, wherein the EVS transistor of each of the plurality of pixels is configured to selectively couple a first photosensor of the plurality of photosensors of that pixel to a corresponding one of the plurality of event driven circuits; and
a threshold comparison stage coupled to each of the plurality of event driven circuits.

18. The system of claim 17, wherein the imaging system is operable in a monochrome CMOS image sensor (CIS)/EVS hybrid mode in which (i) each of the plurality of pixels is configured to simultaneously provide CIS information and EVS information and (ii) the EVS information from different ones of plurality of pixels disposed under different colored ones of the plurality of color filters are mixed prior to reaching the threshold comparison stage.

19. The system of claim 17, wherein the imaging system is operable in a color CMOS image sensor (CIS)/EVS hybrid mode in which (i) each of the plurality of pixels is configured to simultaneously provide CIS information and EVS information and (ii) the EVS information from different ones of plurality of pixels disposed under different colored ones of the plurality of color filters reach the threshold comparison stage at different times without mixing.

20. The system of claim 17, wherein each event driven circuit of the plurality of event driven circuits includes memory elements configured to receive and store information corresponding to only one color of the plurality of color filters.

21. The system of claim 17, further comprising a plurality of switches, each of the plurality of switches selectively coupling a corresponding one of the plurality of event driven circuits to the threshold comparison stage.

22. The system of claim 17, wherein each of the plurality of event driven circuits includes:
a photocurrent-to-voltage converter coupled to the EVS transistor of the corresponding one of the plurality of pixels; and
a difference circuit coupled between the photocurrent-to-voltage converter and the threshold comparison stage.

23. The system of claim 17, wherein each event driven circuit of the plurality of event driven circuits is dedicated to only the corresponding one of the plurality of pixels.

24. The system of claim 17, wherein the threshold comparison stage includes an up event comparator and a down event comparator coupled in parallel between (i) the plurality of event driven circuits and (ii) a logic and handshake circuit that is shared amongst the plurality of pixels.

25. The system of claim 17, wherein:
the plurality of pixels and the color filter array are disposed in and/or on a first die;
the plurality of event driven circuits and the threshold comparison stage are disposed in and/or on a second die stacked with the first die; and
each of the plurality of event driven circuits is coupled to the corresponding one of the plurality of pixels via a stacked pixel level connection (SPLC).
